(19) United States
(12) Patent Application Publication
(10) Pub. No.: US 2006/0148197 A1
(43) Pub. Date: Jul. 6, 2006

(54) Method for forming shallow trench isolation with rounded corners by using a clean process

(76) Inventors: Chia-Wei Wu, Houli Township (TW); Cheng-Shun Chen, JhunanTownship (TW); Jung-Yu Hsieh, Hsihchu (TW); Ling Wu Yang, Taichung (TW)

Correspondence Address: RABIN & Berdo, PC, 1101 14TH STREET, NW, SUITE 500, WASHINGTON, DC, 20005, US

(21) Appl. No.: 11/134,372

(22) Filed: May 23, 2005

(30) Foreign Application Priority Data
Dec. 30, 2004 (TW) 093141458

(51) Int. Cl. H01L 21/76; H01L 21/302

(52) U.S. Cl. 438/424; 438/745

(57) ABSTRACT

In a method for forming STI in a silicon substrate having a pad oxide over the substrate, a hard mask is formed over the pad oxide, the hard mask and the pad oxide are patterned to form an opening, the silicon substrate is etched through the opening to form a trench, a liner oxide is formed over the trench, an STI insulator is formed in the trench, and the hard mask and the pad oxide are removed. Before the formation of the liner oxide, a clean process is performed that comprises applying silicon-consuming solution to round the top corners of the trench.

### FIELD OF THE INVENTION

The present invention is related generally to a semiconductor process and more particularly, to a method for forming shallow trench isolation (STI) in a silicon substrate.

### BACKGROUND OF THE INVENTION

In a semiconductor process, local oxidation of semiconductor (LOCOS) is used most frequently for the isolation of active areas in a chip. However, LOCOS is disadvantageous due to the bird's beak grown accompanying the oxidation that infringes into the active areas. Specifically, when the channel length of a MOS device is shrunk down to below 0.25 μm, LOCOS is hard to meet the requirements of insulation and integration on the chip any more. As a matter of fact, STI is the most important and prevailing technology utilized in the manufacture of MOS devices below 0.25 μm, by which silicon dioxide (SiO₂) is formed to fill in the STI trench, followed by chemical mechanical polishing (CMP). As such, not only global planarization is achieved, but also the bird's beak may almost be neglected. Moreover, the density of integrated circuit may be maximized.

Referring to FIG. 1, in a typical STI process, a pad oxide 12 and a nitride 14 are sequentially formed on a silicon substrate 10, an opening 16 is formed in the pad oxide 12 and the nitride 14 after lithographic and etch processes to expose the silicon substrate 10, the silicon substrate 10 is etched through the opening 16 to form a trench 18, liner oxide (LINOX) is grown on the exposed surfaces of the trench 18 by LINOX process, STI oxide is filled in the trench 18, CMP is carried out for planarization, and the nitride 14 and the pad oxide 12 are removed. However, as shown in FIG. 2, when a gate oxide 20 is deposited subsequently to the STI process, the oxide around the STI top corners 22 becomes thinner due to stress in the oxide formation, such that the MOS device formed thereafter has a reduced breakdown voltage and an increased current leakage, and the performance of the MOS device is degraded. This inferiority is caused by the proximately right-angled top corners 22. Referring to FIG. 3 for an enlarged view, during the deposition of the gate oxide 20, the oxide 24 on the silicon substrate 10 and another one 26 on the sidewalls of the STI trench push each other and result in the oxide 28 at the top corner 22 thinner. Rounding the top corner 22 could suppress the STI top corner thinning.

Treatment to the STI top corners is essential to the inhibition of the corner effect and the maintenance of gate oxide integrity. In the STI process proposed in U.S. Pat. No. 6,670,279 issued to Pai et al., a spacer oxide is formed on the sidewalls of the pad oxide and the pad nitride before etching the STI trench to serve as a mask to etch a portion of the STI trench, and the STI trench is further completely etched after removing the spacer oxide. In this case, rounded STI corners are obtained in the oxidation of the subsequent LINOX process. By this method, although the STI corner thinning is prevented, the process steps and process time in the STI process increase due to the utilization of the spacer oxide, and the cost also increase. Particularly, the oxide deposition or the polysilicon deposition and oxidation to produce the spacer oxide is time consuming, and furthermore, the etching of the STI trench is separated into two discontinuous steps that increase the manufacturing time and cost considerably. In addition, as the tendency of reduced dimensions of the semiconductor devices prevails, not only the spacer oxide formation becomes more difficult, but also the shrunk device dimension and density are limited.

Therefore, it is desired a method to form STI with rounded corners with fewer steps, shorter time and lower cost.

### SUMMARY OF THE INVENTION

One object of the present invention is to provide a simple, rapid and cost efficient method to solve the STI top corner thinning problem.

Specifically, one object of the present invention is to provide a method to form STI with rounded top corners.

In a method for forming STI in a silicon substrate having a pad oxide over the substrate, comprising forming a hard mask over the pad oxide, patterning the hard mask and the pad oxide to form an opening, etching the silicon substrate through the opening to form a trench, forming a liner oxide over the trench, forming an STI insulator in the trench, and removing the hard mask and the pad oxide, according to the present invention, silicon-consuming solution is used in a clean process before the formation of the liner oxide (LINOX), to thereby round the top corners of the trench.

Particularly, the LINOX clean originally in the LINOX process is used for the clean process to solve the STI top corner thinning. Due to using the silicon-consuming solution in the clean process before the formation of the LINOX to round the top corners of the trench, no additional steps are introduced in the STI process, no time-consuming process is required, and the method is cost efficient.

### BRIEF DESCRIPTION OF DRAWINGS

These and other objects, features and advantages of the present invention will become apparent to those skilled in the art upon consideration of the following description of the preferred embodiments of the present invention taken in conjunction with the accompanying drawings, in which:

FIG. 1 is a schematic diagram to illustrate a typical STI process;

FIG. 2 is a schematic diagram to illustrate an STI top corner thinning resulted from the STI process shown in FIG. 1;

FIG. 3 is an enlarged view of the top corner of the STI shown in FIG. 2;

FIG. 4 is a diagram schematically illustrating a structure after a pad oxide and a hard mask are sequentially formed over a silicon substrate and a photoresist is coated thereafter;

FIG. 5 is a diagram schematically illustrating a structure after the hard mask and the pad oxide are etched;

FIG. 6 is a diagram schematically illustrating a structure after a trench is etched;

FIG. 7 is a diagram schematically illustrating a structure after the edges of the hard mask and the pad oxide are pulled back;

FIG. 8 is a diagram schematically illustrating a structure after a clean process is performed;

FIG. 9 is a diagram schematically illustrating a structure after a liner oxide (LINOX) is formed;

FIG. 10 is a diagram schematically illustrating a structure after an insulator is deposited;

FIG. 11 is a diagram schematically illustrating a structure after the insulator is etched back;

FIG. 12 is a diagram schematically illustrating a structure after the hard mask is removed;

FIG. 13 is a diagram schematically illustrating a structure after the pad oxide is removed; and

FIG. 14 is a diagram schematically illustrating a structure in another embodiment after a clean process is performed.

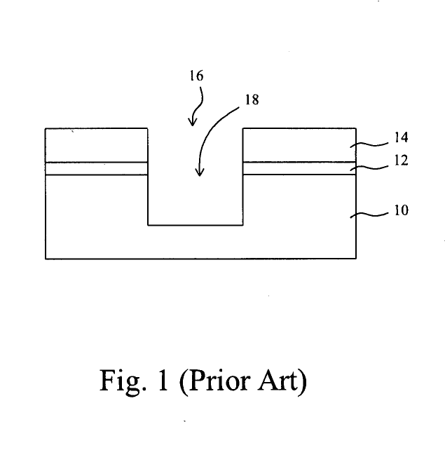

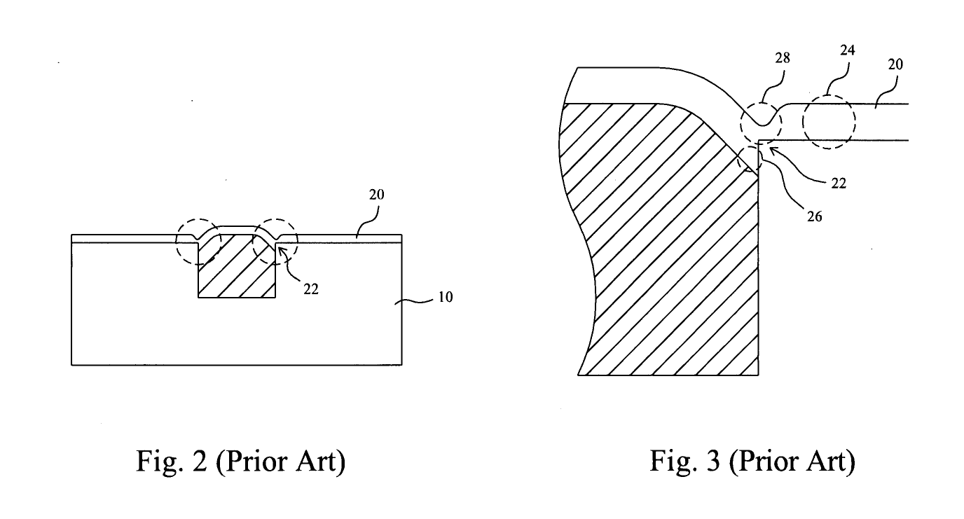

### DETAILED DESCRIPTION OF THE INVENTION

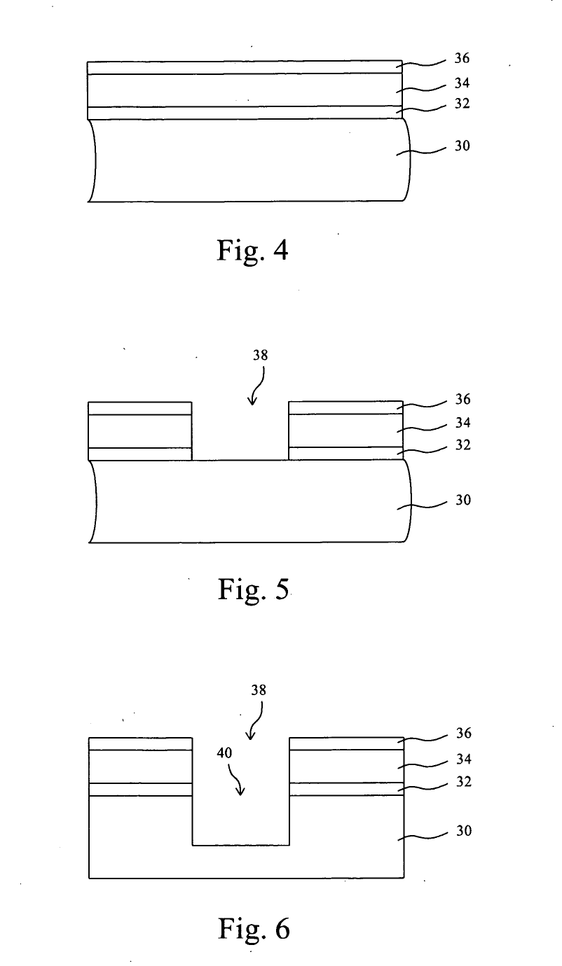

FIG. 4 to FIG. 13 show a process flow according to one embodiment of the present invention. In an STI process, a wafer is first placed into a cleaning tank to remove impurities or particles on the wafer by physical or chemical methods, such as standard RCA clean or its modifications, to exempt these particles or impurities from bringing adverse effects to the subsequent processes and resulting in the manufactured devices to fail to operate normally.

After the wafer clean, as shown in FIG. 4, on the silicon substrate 30 a pad oxide 32 and a hard mask 34 are formed in turn, and then a photoresist 36 is coated thereon. The pad oxide 32 is formed to serve as a buffer layer between the silicon substrate 30 and the hard mask 34, and it may be carried out by thermal oxidation in a high temperature environment containing oxygen (O₂) gas or moisture to grow oxide (SiO₂) having a thickness of 100-300 Å. The hard mask 34 may be silicon nitride Si₃N₄ or SiₓN_{y} having a thickness of 800-2500 Å, formed by for example liquid phase chemical vapor deposition (LPCVD) at a temperature of 650-800° C. or plasma enhanced chemical vapor deposition (PECVD) at a temperature of 250-400° C.

Referring to FIG. 5, the photoresist 36 is developed by lithographic process to define an STI pattern, and the patterned photoresist 36 is used as a mask to etch the hard mask 34 and the pad oxide 32, so as to form an opening 38 penetrating through the hard mask 34 and the pad oxide 32 to reach the silicon substrate 30. Preferably, the hard mask 34 and the pad oxide 32 are etched by dry etching to stop at the surface of the silicon substrate 30.

Referring to FIG. 6, a further etch is performed through the opening 38 downward into the silicon substrate 30 to form a trench 40 in the silicon substrate 30. In the case that plasma etch is employed for the formations of the opening 38 and the trench 40, the processes shown in FIG. 5 and FIG. 6 may be carried out in a same chamber, for example using the patterned photoresist 36 as a mask to etch the hard mask 34, the pad oxide 32 and the silicon substrate 30 until the trench 40 is formed.

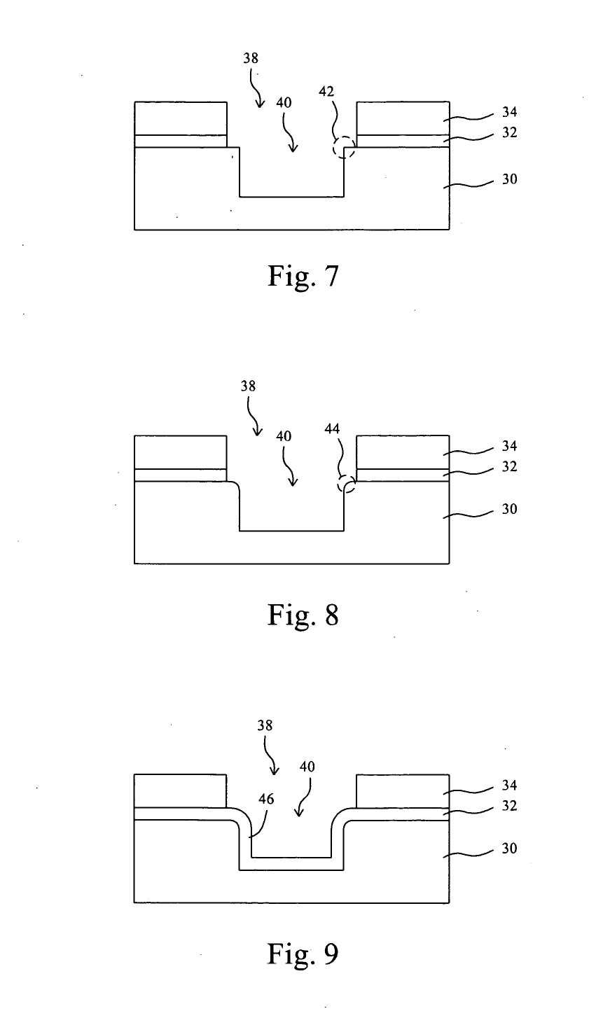

The photoresist 36 is then removed by ozone (O₃) ashing and sulfuric acid (H₂SO₄) soaking. As shown in FIG. 7, the edges of the hard mask 34 and the pad oxide 32 close to the trench 40 are pulled back by etching the hard mask 34 and the pad oxide 32, so as to expose the top corners 42 of the trench 40. Alternatively, the product shown in FIG. 6 is dipped in high temperature phosphoric acid (H₃PO₄) to remove the photoresist 36, and at the same time, the edges of the nitride 34 are etched. The resultant structure is further dipped in hydrofluoric acid (HF) to etch the edges of the pad oxide 32. As a result, the top corners 42 of the trench 40 is exposed due to the pull back of the edges of the nitride 34 and the pad oxide 32. In yet another embodiment, the edges of the hard mask 34 and the pad oxide 32 are pulled back by dry etch, for example using the method proposed in U.S. Pat. No. 6,828,248 issued to Tao et al., to thereby form the structure shown in FIG. 7.

Then, a clean process is performed. Preferably, as in a typical STI process, LINOX process is performed, which comprises LINOX clean and LINOX formation. However, the LINOX clean hereof is used to round the top corners 42 of the trench 40 according to the present invention. As shown in FIG. 8, during the clean process, silicon consuming solution is used, which comprises for example SC-1 (APM) solution having temperature higher than 65° C., NH₄OH rich SC-1 solution, i.e., SC-1 solution having NH₄OH (ammonia water) concentration higher than H₂O₂ (hydrogen peroxide) concentration, O₃—HF mixed (FPM) solution, acid erosive to silicon, or any other solutions containing silicon eroding compositions such as potassium hydroxide (KOH). Therefore, in the clean process, the top corners 42 of the trench 40 will become rounded top corners 44, due to the presence of the silicon consuming solution.

Referring to FIG. 9, a liner oxide (LINOX) 46 is subsequently grown up on the exposed surfaces of the trench 40 in a high temperature furnace to have a thickness of 150-700 Å. Optionally, a silicon nitride may be further deposited on the liner oxide 46.

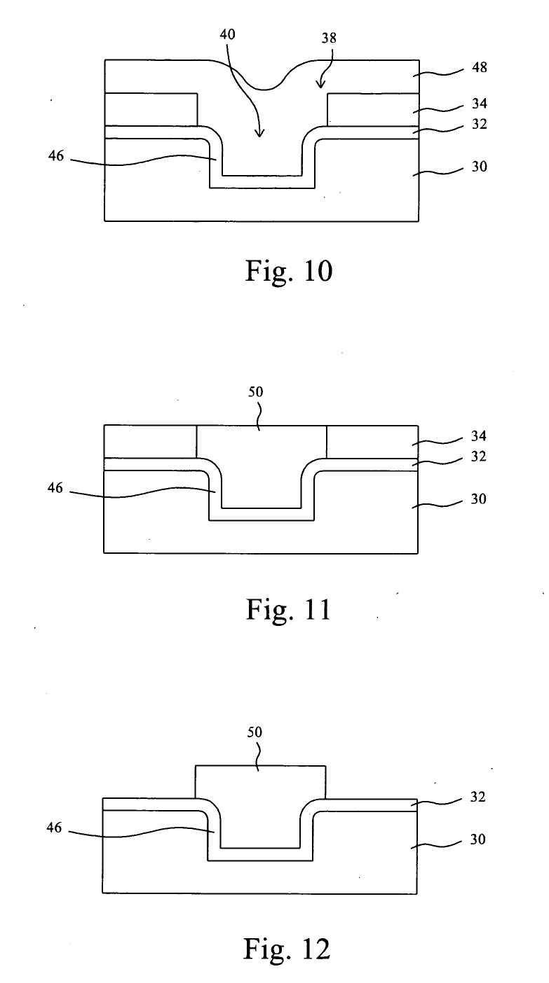

As shown in FIG. 10, an insulator 48 is deposited to fill in the trench 40, for example by high density plasma chemical vapor deposition (HDP-CVD) to deposit SiO₂ completely covered over the trench 40 and the opening 38.

Referring to FIG. 11, the insulator 48 is etched back by for example chemical mechanical polishing (CMP) to stop at the top surface of the hard mask 34, thereby planarizing the top surface and leaving an STI insulator 50.

As shown in FIG. 12, the hard mask 34 is then removed. For example, in the case that the hard mask 34 is silicon nitride, H₃PO₄ solution of 180° C. or H₃PO₄ and H₂O₂ mixed solution is used to etch the silicon nitride 34 with the oxides 32 and 50 as barrier layers.

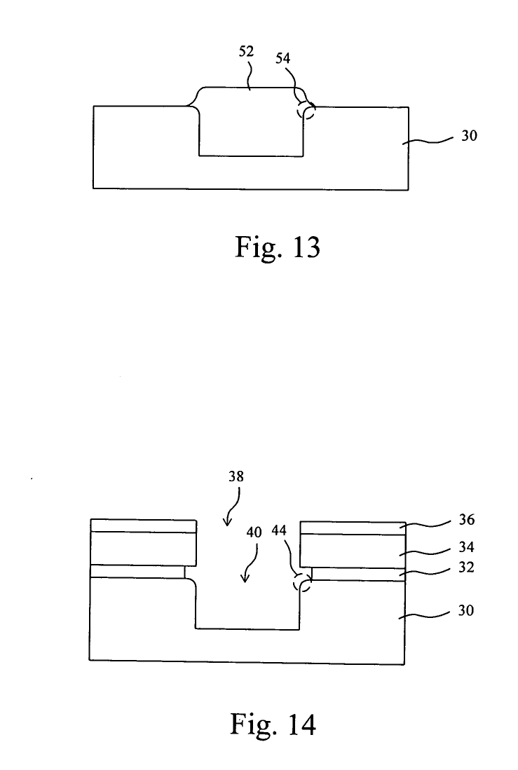

Referring to FIG. 13, the pad oxide 32 is removed, for example by diluted HF (DHF) solution or additionally introduced with ammonium fluoride as a buffer agent. In the finished STI structure 52, the liner oxide 46 and the HDP oxide 50 are combined together, and rounded top corners 54 are obtained. Preferably, a rapid thermal process (RTP) is further applied, for the oxide 52 to become denser.

Another embodiment for the clean process is shown in FIG. 14. After the steps illustrated by FIG. 4 to FIG. 6, chemical solution having a higher etch rate to oxide than that to silicon is chosen to be used in the clean process, for example including HNO₃ and HF mixed solution or additionally introduced with acetic acid (CH₃COOH) as a buffer agent. In this process, the pad oxide 32 is etched more rapidly than the silicon substrate 30, and hence rounded top corners 44 of the trench 40 are obtained in the clean process. Alternatively, in the clean process, HF solution is used to pull back the edges of the pad oxide 32 to expose the top corners 42 of the trench 40, followed by SC-1 solution having temperature greater than 65° C., NH₄OH rich SC-1 solution, FPM solution, or any other silicon consuming solutions to round the top corners 42 of the trench 40 to be the rounded top corners 44.

According to the present invention, silicon-consuming solution is used in the clean process before the LINOX formation such that the top corners of the STI trench are rounded, without introducing additional steps, and therefore, the STI top corner thinning problem is solved in a simple, rapid and cost efficient manner.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof of the appended claims.

What is claimed is:

1. A method for forming STI in a silicon substrate having a pad oxide formed thereover, the method comprising the steps of:
forming a hard mask over the pad oxide;
patterning the hard mask and the pad oxide for forming an opening;
etching the silicon substrate through the opening for forming a trench in the silicon substrate;
pulling back exposed edges of the pad oxide for exposing top corners of the trench; and
performing a clean process for rounding the exposed top corners of the trench.

2. The method of claim 1, further comprising the steps of:
forming a liner oxide over the trench including portions thereof covered on the rounded top corners of the trench;
depositing an insulator for filling in the trench;
etching back the insulator for leaving an STI insulator in the trench; and
removing the hard mask and the pad oxide.

3. The method of claim 1, wherein the step of pulling back exposed edges of the pad oxide comprises the step of etching the exposed edges of the pad oxide with chemical solution having high etch rate to the pad oxide.

4. The method of claim 3, wherein the chemical solution comprises HF solution.

5. The method of claim 1, wherein the step of performing a clean process comprises the step of applying silicon-consuming solution to the exposed top corners of the trench.

6. The method of claim 5, wherein the silicon-consuming solution comprises SC-1 solution having temperature greater than 65° C.

7. The method of claim 5, wherein the silicon-consuming solution comprises NH₄OH rich SC-1 solution.

8. The method of claim 5, wherein the silicon-consuming solution comprises FPM solution.

9. The method of claim 2, wherein the step of etching back the insulator comprises the step of carrying out CMP process for planarization.

10. A method for forming STI in a silicon substrate having a pad oxide formed thereover, the method comprising the steps of:
forming a hard mask over the pad oxide;
patterning the hard mask and the pad oxide for forming an opening;
etching the silicon substrate through the opening for forming a trench in the silicon substrate, the trench having top corners; and
performing a clean process for rounding the top corners of the trench.

11. The method of claim 10, further comprising the steps of:
forming a liner oxide over the trench including portions thereof covered on the rounded top corners of the trench;
depositing an insulator for filling in the trench;
etching back the insulator for leaving an STI insulator in the trench; and
removing the hard mask and the pad oxide.

12. The method of claim 10, wherein the step of performing a clean process comprises the steps of:
applying chemical solution to exposed edges of the pad oxide, the chemical solution having high etch rate to the pad oxide; and
applying silicon-consuming solution to the top corners of the trench.

13. The method of claim 12, wherein the chemical solution comprises HF solution.

14. The method of claim 12, wherein the silicon-consuming solution comprises SC-1 solution having temperature greater than 65° C.

15. The method of claim 12, wherein the silicon-consuming solution comprises NH₄OH rich SC-1 solution.

16. The method of claim 12, wherein the silicon-consuming solution comprises FPM solution.

17. The method of claim 10, wherein the step of performing a clean process comprises the step of applying chemical solution to exposed edges of the pad oxide and the top corners of the trench, the chemical solution having a first etch rate to the pad oxide and a second etch rate to the silicon substrate, the first etch rate higher than the second etch rate.

18. The method of claim 17, wherein the solution comprises HNO₃ solution and HF solution.

19. The method of claim 11, wherein the step of etching back the insulator comprises the step of carrying out CMP process for planarization.
